(19) United States
(12) Patent Application Publication
(10) Pub. No.: US 2025/0048686 A1
(43) Pub. Date: Feb. 6, 2025

(54) One-Time Programming Memory Device with Backside Isolation Structure

(71) Applicant: Taiwan Semiconductor Manufacturing Company, Ltd., Hsin-Chu (TW)

(72) Inventors: Ping-Wei Wang, Hsin-Chu (TW); Gu-Huan Li, Hsinchu County (TW); Jui-Lin Chen, Taipei City (TW)

(21) Appl. No.: 18/410,195

(22) Filed: Jan. 11, 2024

Related U.S. Application Data
(60) Provisional application No. 63/517,409, filed on Aug. 3, 2023.

(51) Int. Cl. H01L 29/06; H01L 21/8238; H01L 23/522; H01L 23/528; H01L 27/092; H01L 29/423; H01L 29/66; H01L 29/775; H01L 29/786; H10B 20/25

(52) U.S. Cl. CPC H01L 29/0649; H01L 21/823807; H01L 21/823814; H01L 21/823878; H01L 23/5226; H01L 23/5283; H01L 27/092; H01L 29/0673; H01L 29/42392; H01L 29/66439; H01L 29/775; H01L 29/78696; H10B 20/25

(57) ABSTRACT

The present disclosure provides an integrated circuit (IC) structure that includes a semiconductor substrate having a frontside and a backside; a shallow trench isolation (STI) structure formed in the semiconductor substrate and defining an active region, wherein the STI structure includes a STI bottom surface, wherein the semiconductor substrate includes a substrate bottom surface, and wherein the STI bottom surface and the substrate bottom surface are coplanar; a field-effect transistor (FET) over the active region and formed on the frontside of the semiconductor substrate; and a backside dielectric layer disposed on the substrate bottom surface and the STI bottom surface.

### PRIORITY DATA

This application claims priority to U.S. Provisional Patent Application No. 63/517,409 filed on Aug. 3, 2023, entitled “INTEGRATED CIRCUIT WITH ENHANCED ISOLATION” (Attorney Docket No. P2023-0855/24061.4858PV01), the entire disclosure of which is hereby incorporated herein by reference.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

Recently, multigate devices have been introduced to improve gate control. Multigate devices have been observed to increase gate-channel coupling, reduce OFF-state current, and/or reduce short-channel effects (SCEs). One such multigate device is the gate-all around (GAA) device, which includes a gate structure that can extend, partially or fully, around a channel region to provide access to the channel region on at least two sides. GAA devices enable aggressive scaling down of IC technologies, maintaining gate control and mitigating SCEs, while seamlessly integrating with conventional IC manufacturing processes. As GAA devices continue to scale, challenges have arisen in some areas, such current leakage, especially when high current, high voltage or high speed is needed. Accordingly, although existing GAA devices and methods for fabricating such have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a top view of an integrated circuit structure according to various aspects of the present disclosure.

FIG. 2 is a sectional view of the integrated circuit structure according to various aspects of the present disclosure.

FIG. 3A is a top view of an integrated circuit structure according to various aspects of the present disclosure.

FIGS. 3B, 3C and 3D are sectional views of the integrated circuit structure of FIG. 3A according to various aspects of the present disclosure.

FIG. 4A is a top view of an integrated circuit structure according to various aspects of the present disclosure.

FIG. 4B is a sectional view of the integrated circuit structure of FIG. 4A according to various aspects of the present disclosure.

FIGS. 5A, 5B and 5C are flowcharts of a method for fabricating of the integrated circuit structure according to various aspects of the present disclosure.

FIGS. 6A, 7A, 8A, 9A, 10A and 11A are fragmentary perspective views of the integrated circuit structure, in portion or entirety, at various fabrication stages according to various aspects of the present disclosure.

FIGS. 6B, 7B, 8B, 9B, 10B and 11B are fragmentary sectional views of the integrated circuit structure, in portion or entirety, at various fabrication stages according to various aspects of the present disclosure.

### DETAILED DESCRIPTION

The present disclosure relates generally to integrated circuit devices, and more particularly, to multigate devices, such as gate-all-around (GAA) devices.

The following disclosure provides many different embodiments, or examples, for implementing different features. Reference numerals and/or letters may be repeated in the various examples described herein. This repetition is for the purpose of simplicity and clarity and does not in itself dictate a relationship between the various disclosed embodiments and/or configurations. Further, specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. Moreover, the formation of a feature on, connected to, and/or coupled to another feature in the present disclosure may include embodiments in which the features are formed in direct contact, and may also include embodiments in which additional features may be formed interposing the features, such that the features may not be in direct contact.

Further, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used herein for ease of description to describe one element or feature's relationship to another element(s) or feature(s). The spatially relative terms are intended to encompass different orientations than as depicted of a device (or system or apparatus) including the element(s) or feature(s), including orientations associated with the device's use or operation. The apparatus may be otherwise oriented (rotated 90 degrees or at other orientations) and the spatially relative descriptors used herein may likewise be interpreted accordingly. Still further, when a number or a range of numbers is described with “about,” “approximate,” and the like, the term is intended to encompass numbers that are within a reasonable range including the number described, such as within +/−10% of the number described, or other values as understood by person skilled in the art. For example, the term “about 5 nm” may encompass the dimension range from 4.5 nm to 5.5 nm.

The disclosed device structure and the method making the same are related to field-effect transistors (FETs), especially GAA FET structure. The disclosed device structure includes various structure features and fabrication steps to provide collective isolation and prevent the device structure from current leakage. The disclosed structure having one One-Time-Programmable Memory (OTP) device and the method making the same is taken as an example. However, it is understood that the disclosure is not limited to OPT devices and is applicable to any proper device for leakage reduction.

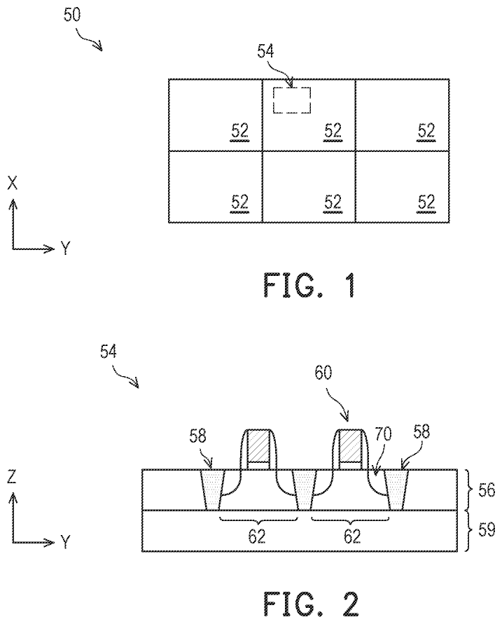

FIG. 1 is a top view of an integrated circuit (IC) structure 50 having various circuit regions 52 each having one or more OTP devices. However, those OTP circuit regions 52 are disposed side by side without margin area therebetween. This is because the device pickup regions are limited due to various isolation features, which will be described below, according to various embodiments of the present disclosure. It is understood that the disclosure is not limited to OPT devices and is applicable to any proper device for leakage reduction. The OPT device usually implements an electrical fuse (eFuse) and need high voltage operation. The current leakage is a concern in such application. Many measures have been used to reduce the current leakage. For example, a N-type FET (nFET) in the OPT device includes a P-well and a deep N-well (DNW) underlying the P-well, a P-well pickup region for biasing the P-well, and a N-well pickup for biasing the deep N-well. This structure may reduce the current leakage but increase device area and reduce the circuit packing density.

In some embodiments of the present disclosure, the method to form a device structure includes, after forming FETs in fin structure or GAA structure, includes operations to thin down the substrate from the backside to reach the bottom surface of the shallow trench isolation (STI) structure so that the semiconductor substrate is separated into a plurality of semiconductor islands that are isolated from each other by the STI structure, thereby achieving isolation of those semiconductor islands and reduction of leaking current. Thus, those well pickup regions for junction isolation are eliminated with the circuit area reduction more than 80%. Therefore, the disclosed device structure is also referred to as tap-less device structure.

A portion 54 of the IC structure 50 is further illustrated in FIG. 2. FIG. 2 is a sectional view of the IC structure 50 constructed in accordance with some embodiments. The IC structure 50 includes a semiconductor substrate 56, such as a silicon substrate, a gallium arsenide substrate, or other suitable semiconductor substrate. An isolation structure 58 is formed in the semiconductor substrate 56 and separates the semiconductor substrate 56 along Y direction, defining active regions 62 of the semiconductor substrate 56. Those active regions are surrounded by the isolation structure and separated from each other by the isolation structure. In the present disclosure, the isolation structure 58 are shallow trench isolation (STI) structure formed by a proper procedure that includes patterning, deposition, and chemical mechanical polishing (CMP). Those active regions may be extruded above the STI structure and are referred to as fin active regions accordingly. The IC structure 50 includes various field-effect transistors (FETs) formed on the active regions. A field-effect transistor includes a gate 60, source/drain (S/D) features (or simply a source and a drain) 70 interposed by the gate 60. The gate 60 includes a gate dielectric layer and a gate electrode disposed on the gate dielectric layer, and a gate spacer disposed on sidewalls of the gate electrode. The FET may be a planar FET, a fin FET, a multi-gate FET such as a gate-all-around (GAA) FET or other suitable FET structure. The FETs are formed on the frontside of the semiconductor substrate 56. The method to form the IC structure includes thinning down the semiconductor substrate 56 from the backside such that the STI structure 58 are exposed. The bottom surface of the semiconductor substrate 56 and the bottom surface of the STI structure 58 are coplanar after thin-down. Other structure, such as interconnect structure, is formed on the frontside. Backside interconnect structure 59 is formed on the backside of the semiconductor substrate 56 after thin-down.

The above disclosed structure provides isolation for various FETs distributed along Y direction (along longitudinal direction of gates). However, various FETs distributed along X direction (along longitudinal direction of active regions such as fin active regions) on one active region are not properly isolated from each other. The structure in the present disclosure also includes multiple features to collectively achieve enhanced isolation for those FETs as described below.

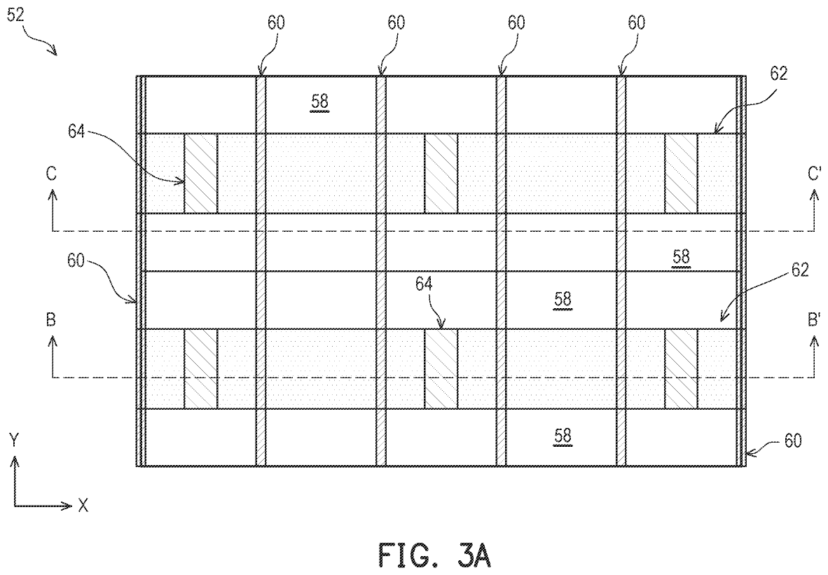

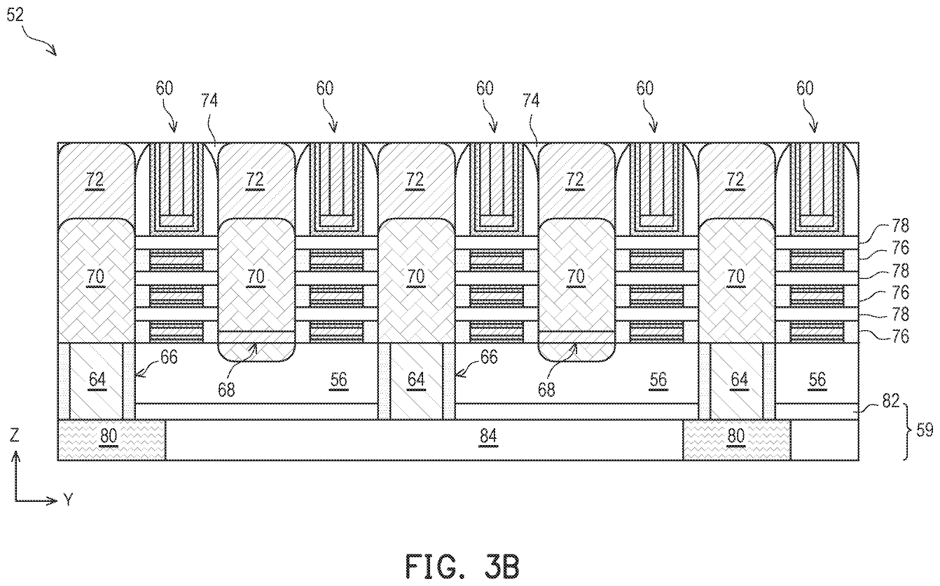

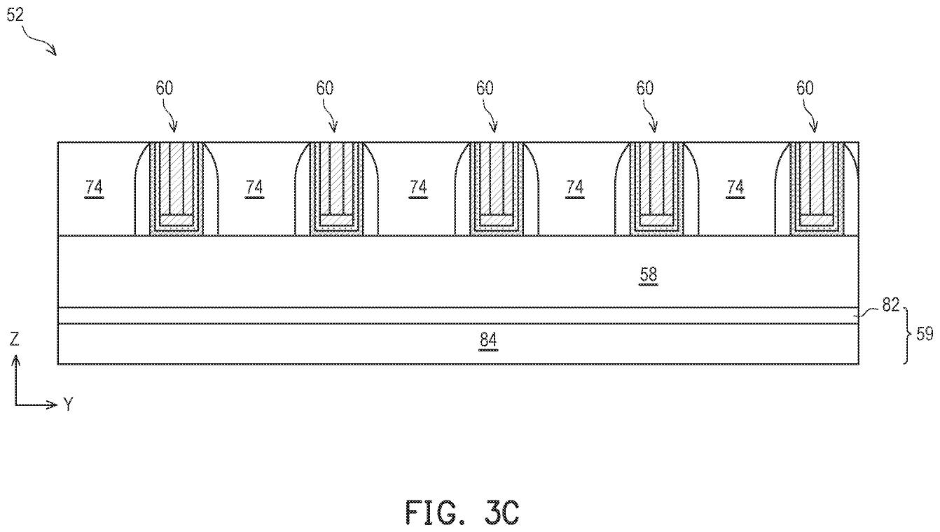

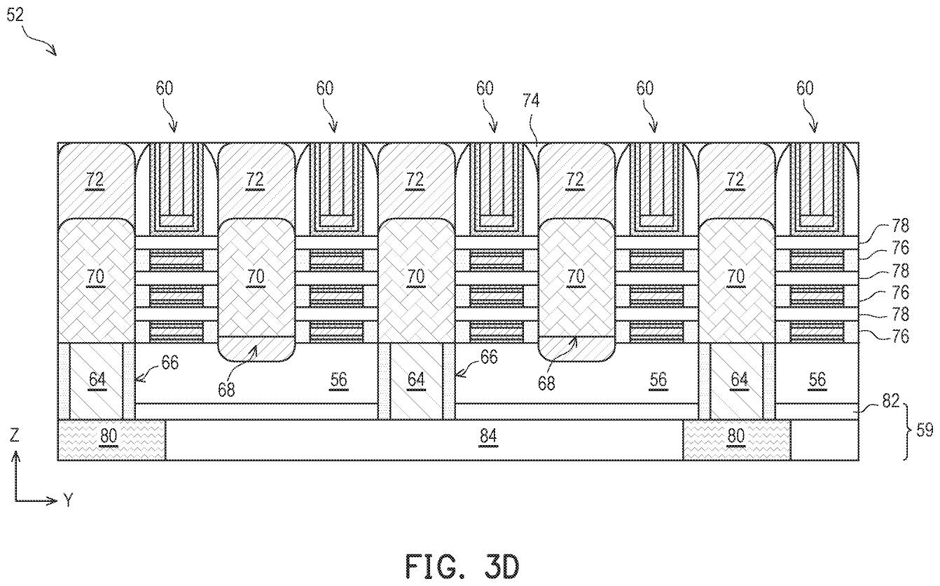

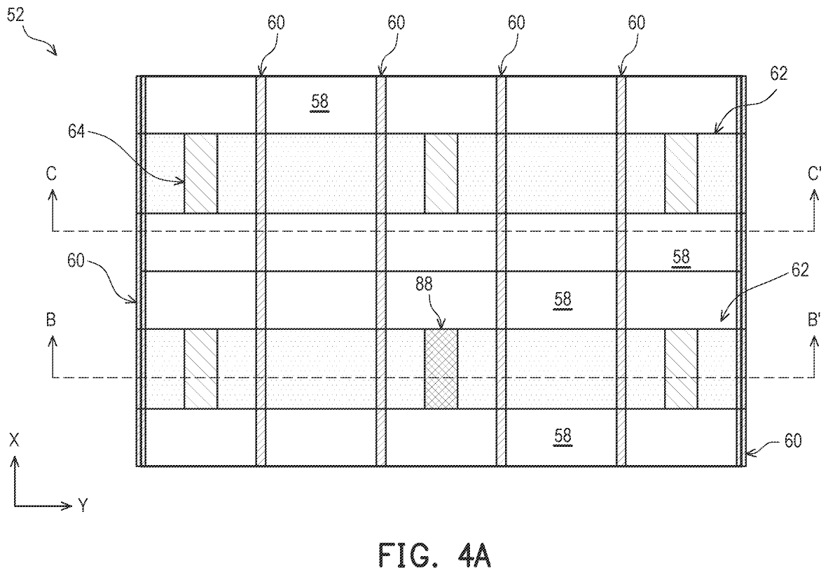

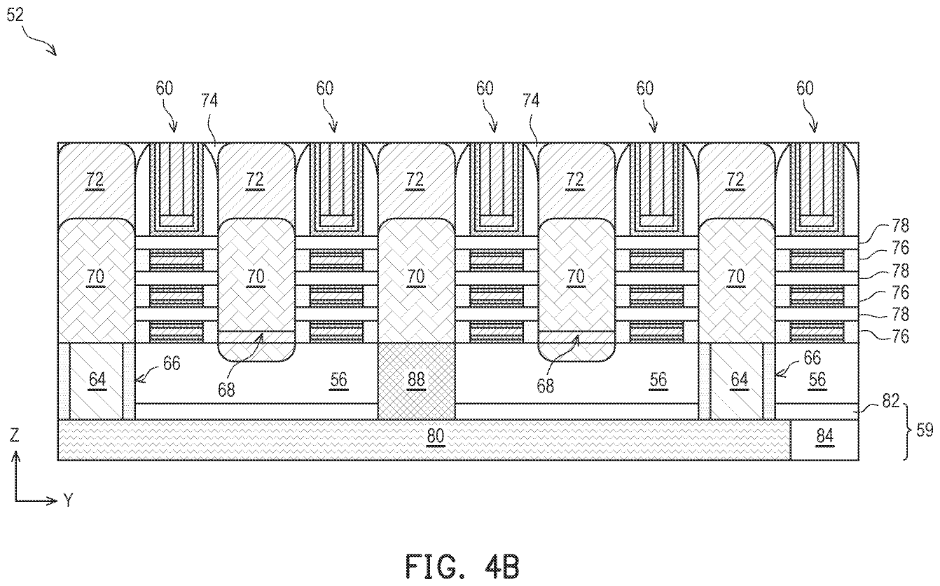

FIG. 3A illustrates a top view of the IC structure 50 while FIGS. 3B (and 3D) and 3C illustrate sectional views of the IC structure 50 along the dashed lines BB′ and CC′, respectively, constructed according to some embodiments. In FIG. 3A, the device structure includes active regions 62 oriented along X direction and gates 60 oriented along Y direction. Conductive features (backside via or “VB”) 64 are formed from the backside of the substrate 56. The backside vias 64 are conductive features and are portions of the backside interconnect structure 59 for electrical routing. The backside vias 64 are electrically connected to FETs, such as connected to S/D features 70 from the backside. In some embodiments, a subset of the backside vias 64 are replaced by backside dielectric vias for isolation function, such as those illustrated in FIGS. 4A and 4B. The backside dielectric vias are dielectric features and are different from the backside conductive vias. The formation of the backside conductive vias and the backside dielectric features will be further described later.

In FIG. 3B, Various devices including FETs such as GAA FETs are formed on the frontside of the substrate 56. The FETs includes vertically stacked multiple channel layers 78, source/drain (S/D) features (or simply a source and a drain) 70, and gate structures (or simply gates) 60 interposed between the S/D features 70 and overlying the channel layers 78. The gate structures 60 further extend to wrap around each of the vertically stacked channel layers 78. The gate structures 60 includes a gate dielectric layer, a gate electrode disposed on the gate dielectric layer, and a gate spacer disposed on sidewalls of the gate electrode.

Furthermore, the S/D features 70 are formed with a dielectric feature 68 embedded, thereby achieving the corresponding S/D features 70 from the semiconductor substrate 56. The dielectric feature 68 may include any suitable dielectric material, such as silicon nitride, silicon oxide, silicon oxynitride, other suitable dielectric material or a combination thereof. The formation of the S/D features 70 with the dielectric layer embedded therein may include etching to recess the S/D regions; epitaxially growing a semiconductor material with a lower doping concentration (such as doped with phosphorous for N-type FETs or with boron for P-type FETs); forming dielectric features 68; and epitaxially growing the semiconductor material with a higher doping concentration. The semiconductor material may include silicon, silicon germanium, or other suitable semiconductor material. The forming of the dielectric feature 68 may include depositing the dielectric material(s) and an anisotropic etching such as plasma etch to remove the portions deposited on sidewalls of the recesses.

In some alternative embodiments, the dielectric feature 68 is formed on the bottom surface of the epitaxial S/D feature 70 as illustrated in FIG. 3D. FIG. 3D is a sectional view of the IC structure 50 constructed according to some embodiments. FIG. 3D is similar to FIG. 3B but the dielectric feature 68 is formed on the bottom surface of the S/D feature 70. For example, the formation of the S/D features 70 with the dielectric layer embedded therein may include etching to recess the S/D regions; forming dielectric features 68; and epitaxially growing a semiconductor material with a lower doping concentration (such as doped with phosphorous for N-type FETs or with boron for P-type FETs). The epitaxially growing process may include epitaxially growing a semiconductor material with a lower doping concentration and epitaxially growing the semiconductor material with a higher doping concentration. The forming of the dielectric feature 68 may include depositing the dielectric material(s) and an anisotropic etching such as plasma etch to remove the portions deposited on sidewalls of the recesses.

A frontside interconnect structure is further formed over the FETs. The frontside interconnect structure includes contacts, vias and metal lines distributed in multiple metal layers. Some features (such as contacts 72) of the frontside interconnect structure are illustrated in FIG. 3B. For example, an interlayer dielectric (ILD) layer 74 is formed over the FETs by a proper procedure such as a procedure including deposition and CMP. The ILD layer 74 may include an etch stop layer and a low-k dielectric material disposed on the etch stop layer. The ILD layer 74 is patterned to form contact holes; one or more metal or other conductive material is deposited in the contact holes; and a CMP process is applied to remove excessive metal and planarize the top surface, thereby forming contacts 72 aligned with, landing on and electrically connected to corresponding S/D features 70.

The IC structure 50 also includes the backside vias 64 and other conductive features 80 (such as metal lines) of the backside interconnect structure 59. In some embodiments, after the formation of the FETs (and other devices) and frontside an interconnect structure over FETs, a carrier substrate may be bonded to the frontside. Thereafter, the semiconductor substrate 56 is thinning down from the backside such that the STI structure 58 is exposed from the backside. Other processes may be additionally applied to planarize the backside surface, such etching, deposition, and chemical mechanical polishing (CMP). Accordingly, the bottom surface of the substrate 56 and the bottom surfaces of the STI structures 58 are coplanar. The backside dielectric layer 82 is deposited on the backside and directly contacts the coplanar bottom surfaces of the semiconductor substrate 56 and the STI structures 58, as illustrated in FIGS. 3B and 3C. The backside dielectric layer 82 includes one or more suitable dielectric material such as silicon nitride, silicon oxide, or a combination thereof.

The backside vias 64 are formed in the semiconductor substrate 56 and are electrically connected to the S/D features 70 as illustrated in FIG. 3B. Each of the backside vias 64 includes a metal via (or a metal plug) 64 and a dielectric barrier (or a dielectric barrier layer) 66 surrounding the sidewalls of the backside vias to provide isolation between the adjacent semiconductor islands and the metal plug. In some embodiments, the dielectric barrier layer 66 includes silicon nitride, other suitable dielectric material or a combination thereof. The metal via 64 includes one or more metal such as copper, tungsten, other suitable metal or a combination thereof. The formation of the backside vias 64 includes patterning the backside dielectric layer 82 and the semiconductor substrate 56 to form open holes with corresponding S/D features 70 exposed therewithin; depositing a dielectric barrier material; performing a plasma etching process to remove the portions of the dielectric barrier material deposited on sidewalls of the open holes; depositing the metal to fill in the open holes; and performing a CMP process to planarize, according to some embodiments. Especially, the backside dielectric layer 82 and the dielectric barrier layer 66 surround the semiconductor islands of the semiconductor substrate 56, therefore providing enhanced isolation and reducing the leakage issues.

A backside interlayer dielectric (ILD) layer 84 is formed on the backside dielectric layer 82. The backside ILD layer 84 includes one or more dielectric material, such as an etch stop layer and a low-k dielectric material by suitable technique, such as chemical vapor deposition (CVD), spin-on coating, other suitable technique, or a combination thereof.

Other conductive features, such as metal lines 80, are formed in the backside ILD layer 84 and electrically connected to the backside vias 64 as illustrated in FIG. 3B. The formation of the metal lines 80 may include any proper procedure such as a dual damascene process. For example, the backside ILD layer 84 is patterned to form trenches by lithography process and etching; one or more metal, such as a barrier layer (e.g., titanium and titanium nitride) and a filling metal are sequentially deposited in the trenches; and performing a CMP process to remove excessive deposited metal and planarize the surface.

In FIG. 3B, a first subset of the S/D features 70 are associated with backside vias 64 while a second subset of the S/D features 70 are free of the backside vias 64. The second subset of the S/D features 70 include dielectric feature 68 embedded therein for isolation while the first subset of the S/D features 70 are free of the dielectric feature 68 since those S/D features 70 are intended to be electrically connected to the backside vias 64.

As noted above, the backside vias 64 may have some alternative structure described in FIGS. 4A and 4B. FIG. 4A illustrates a top view of the IC structure 50 while FIG. 4B illustrates a sectional view of the IC structure 50 along the dashed line BB′, constructed according to some embodiments. The IC structure 50 illustrated in FIGS. 4A and 4B is similar to the IC structure 50 illustrated in FIGS. 3A-3B. However, some backside vias 64 are replaced with backside dielectric vias 88. The backside dielectric vias 88 are dielectric features and are configured for isolation with enhance isolation effectiveness. Therefore, the semiconductor islands of the semiconductor substrate 56 are separated and isolated from each other by the backside dielectric vias 88. For clarity, the backside vias 64 are also referred to as backside conductive vias 64.

In FIG. 4A, the device structure includes active regions oriented along X direction and gates oriented along Y direction. Furthermore, the backside dielectric layer 82, the dielectric feature 68, the dielectric barrier layer 66, and the backside dielectric vias 88 are configured to collectively isolate one semiconductor island from adjacent semiconductor islands. In some embodiments, the device structure includes dielectric gate, dielectric gate-cut feature or both to provide additional isolation effect to the semiconductor islands and the FETs formed thereon.

Additional features and methods may be used for further isolation. For example, as illustrated in FIG. 4B, the metal line 80 on the backside is extended along X direction. In FIG. 3B, the metal line 80 on the backside is segmented with a dielectric feature (such as the backside ILD layer 84) inserted to provide additional isolation.

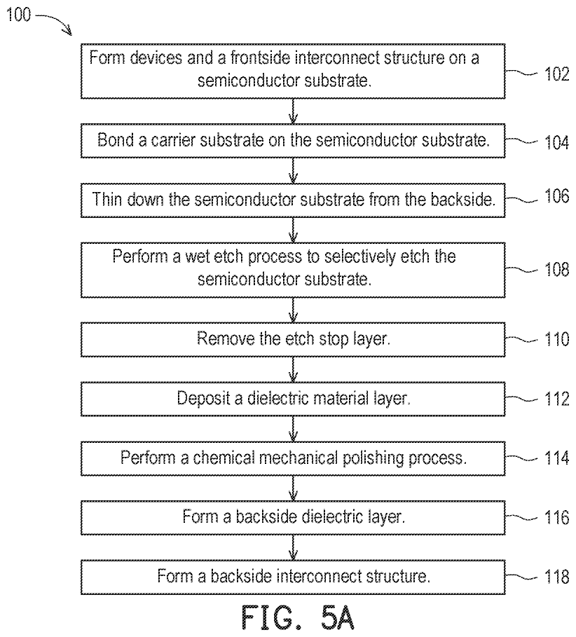

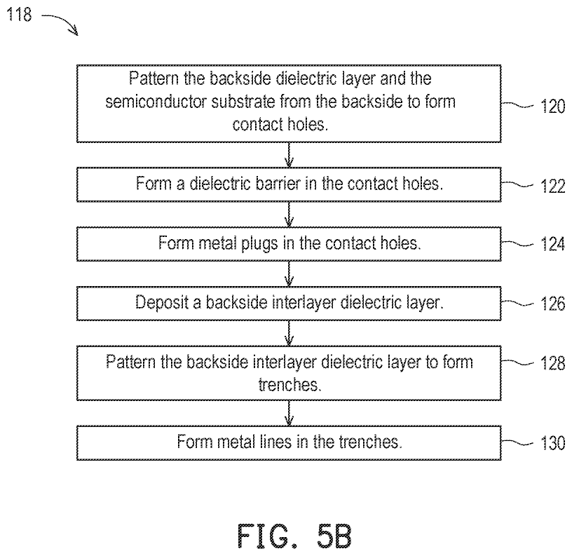

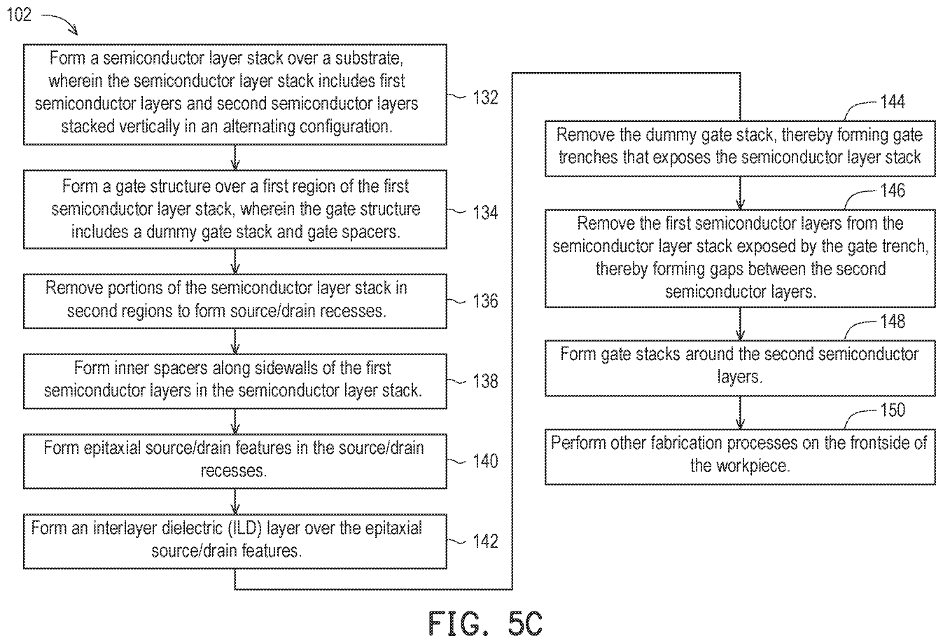

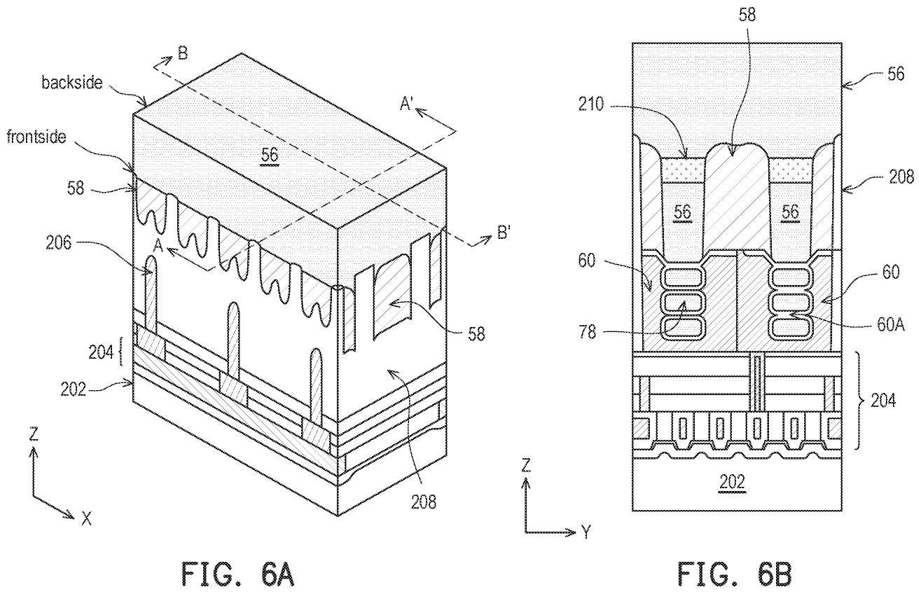

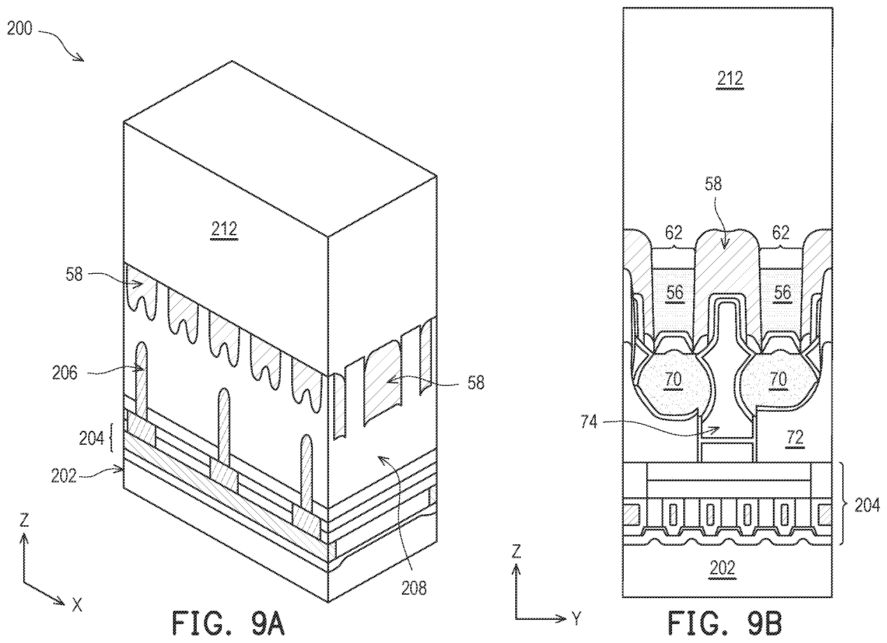

FIGS. 5A, 5B and 5C illustrate a flowchart of a method 100 making the IC structure 50 constructed according to some embodiments. In some examples, the IC structure 50 is an IC structure (or workpiece) 200. FIGS. 6A-11B are perspective views or sectional views of the IC structure 200 at various fabrication stages constructed according to some embodiments. Particularly, FIGS. 6A, 7A, 8A, 9A, 10A and 11A are perspective views of the IC structure 200; FIGS. 6B, 7B, and 8A are sectional views of the IC structure 200 along the dashed lines AA′; and FIGS. 9B, 10B, and 11B are sectional views of the IC structure 200 along the dashed lines BB′. The method 100 is further described below with reference to FIGS. 5A-11B according to some embodiments.

Referring to FIGS. 5A, 6A and 6B, the method 100 begins with a block 102 by providing or receiving a workpiece 200 includes various devices, such as FETs, GAA FETs, complementary FETs (CFETs), other proper devices or a combination thereof, are formed on the frontside of the semiconductor substrate 56, and a frontside interconnect structure 204, including contacts, vias and metal lines, is formed over the devices. In the disclosed embodiment, the devices are GAA FETs with gate structures wrapping around each of the vertically stacked multiple channel layers 78.

Note that workpiece 200 is illustrated in FIGS. 6A and 6B upside-down so that the frontside of the substrate 56 is shown on bottom and the backside of the substrate 56 is on top. Especially, an etch stop layer 210 is formed in the semiconductor substrate 56. The etch stop layer 210 functions as etch stop during the backside processes, as to be described at later operations of the method 100. The etch stop layer 210 is embedded in the semiconductor substrate 56 with a material different from the semiconductor substrate 56 for etch selectivity, The etch stop layer 210 includes any proper material to achieve etch selectivity, such as silicon oxide, silicon nitride, other dielectric materials, other suitable materials or a combination thereof. In some embodiments, the semiconductor substrate 56 is a silicon substrate and the etch stop layer 210 is a silicon germanium or silicon oxide. The etch stop layer 210 may be formed in the semiconductor substrate 56 by any suitable method, such as implanted oxygen (SIMOX), or implantation to introduce other composition. In some embodiments, the etch stop layer 210 is formed by an epitaxial growth, such as epitaxially growing a silicon germanium layer on the semiconductor substrate 56 as the etch stop layer; and epitaxially growing a silicon layer on the silicon germanium layer such that the silicon germanium layer is embedded in the semiconductor substrate 56.

The formation of the frontside structures includes forming the devices and the frontside interconnect structure 204 as described above, and further includes forming other features and components, such as gate-cut features 206 and dielectric gates 208. The gate-cut features 206 are dielectric features and are formed to cut long gate structure into segmented gate structures. The gate-cut features 206 may be formed before, during or after the formation of the gate structure 60 and are longitudinally oriented along the X direction while the gate structures 60 are longitudinally oriented along the Y direction. The dielectric gates 208 are dielectric features as well but are longitudinally oriented along the Y direction and are in parallel with the gate structures. In some embodiments, dummy gate structures are formed and then replaced with the gate structures 60 and the dielectric gates 208, respectively. The gate-cut features 206 are formed to cut the gate structures into segmented gate structure 60. The gate structure 60 includes a gate dielectric layer and a gate electrode disposed on the gate dielectric layer. The portions 60A (such as the gate dielectric layer or additionally portions of the gate electrode) of the gate structure 60 wraps around the channel layers 78.

Still referring to FIGS. 5A, 6A and 6B, the method 100 proceeds to an operation 104 by bonding a carrier substrate 202 to the workpiece 200 on the frontside; and an operation 106 to thin down the semiconductor substrate 56 from the backside. At the operation 106, after the bonding, the semiconductor substrate 56 is thinned down from the backside by a suitable technique, such as grinding, chemical mechanical polishing or a combination thereof. In the disclosed embodiment, the thin-down process reduces the thickness of the substrate 56 such that the STI structure 58 is exposed from the backside. The carrier substrate 202 is a semiconductor substrate (such as a silicon substrate), a dielectric substrate or other suitable substrate according to some embodiments.

The detailed operations to form the devices and the interconnect structure are further described in the flowchart of FIG. 5C.

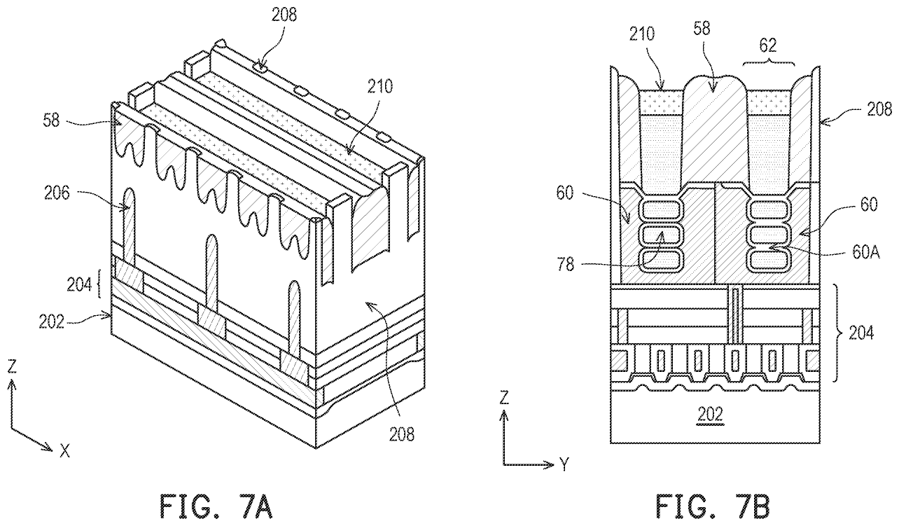

Referring to FIGS. 5A, 7A and 7B, the method 100 proceeds to an operation 108 by performing a wet etch process with an etch solution to selectively etch the semiconductor material of the substrate 56, such as silicon. The wet etch process stops on the etch stop layer 210 due to selective etch so that the etch stop layer 210 is exposed from the backside after the wet etch. In some embodiments, the wet etch process uses potassium hydroxide (KOH) solution, or an etching solution including nitric acid, (HNO₃), hydrofluoric acid (HF) and water (H₂O).

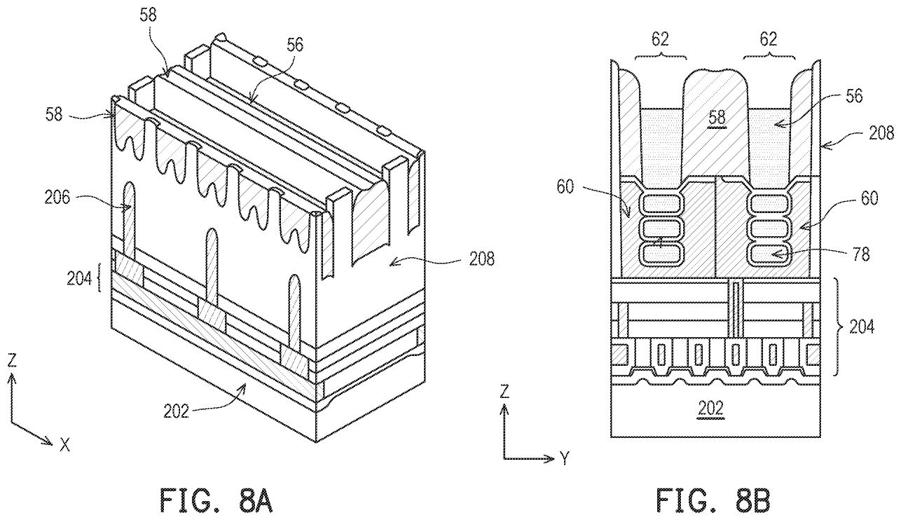

Referring to FIGS. 5A, 8A and 8B, the method 100 proceeds to an operation 110 by selectively removing the etch stop layer 210 by a suitable method, such as another wet etch process with an etchant to selectively remove the etch stop layer 210. Thereafter, the semiconductor substrate 56 with the associated active regions 62 is exposed from backside. In some embodiments, the etching solution includes diluted hydrofluoric acid if the etch stop layer 210 is silicon oxide.

Referring to FIGS. 5A, 9A and 9B, the method 100 proceeds to an operation 112 by depositing a dielectric material layer 212 on the backside using a suitable method such as chemical vapor deposition (CVD), flowable CVD (FCVD), other suitable method or a combination thereof. The dielectric material layer 212 may include silicon oxide, silicon oxynitride, other suitable dielectric material or a combination thereof.

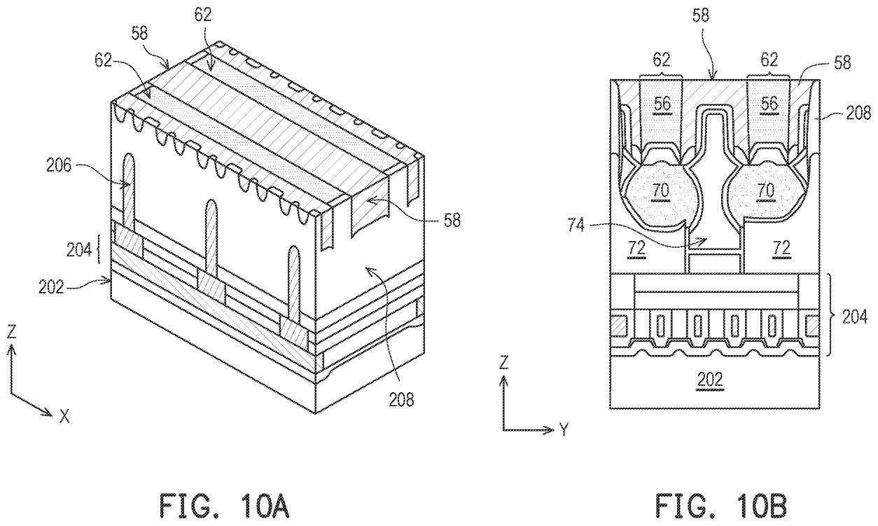

Referring to FIGS. 5A, 10A and 10B, the method 100 proceeds to an operation 114 by performing a CMP process to the backside such that the backside is recessed and planarized until both the STI structure 58 and the semiconductor substrate 56 are exposed from the backside. Accordingly, the bottom surfaces of the STI structure 58 and the semiconductor substrate 56 are coplanar.

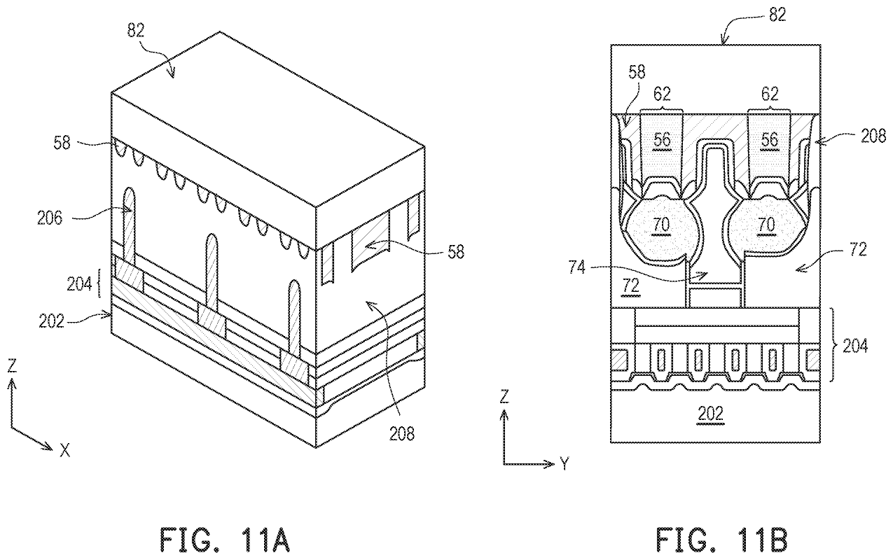

Referring to FIGS. 5A, 11A and 11B, the method 100 proceeds to an operation 116 by forming a backside dielectric layer 82 on the backside using a suitable method such as chemical vapor deposition (CVD), flowable CVD (FCVD), other suitable method or a combination thereof. The backside dielectric layer 82 may include silicon oxide, silicon oxynitride, silicon nitride, other suitable dielectric material or a combination thereof, according to some embodiments. The backside dielectric layer 82 may function as a hard mask, an etch stop layer, dielectric isolation, other functions or a combination thereof.

The method 100 proceeds to an operation 118 to form a backside interconnect structure including backside vias, backside dielectric vias, and backside metal lines distributed in one or more metal layers.

The method 100 may include other processes before, during or after the operations described above.

The backside interconnect structure 59 formed at the operation 118 is similar to the frontside interconnect structure 204 in terms of formation and composition. For example, the backside interconnect structure 59 includes backside vias 64, metal lines 80 and vias distributed in one or more metal layers and can be formed by a suitable technique, such as damascene process, dual damascene process, a procedure including deposition and patterning, other suitable method or a combination thereof. In some embodiments, the backside interconnect structure 59 includes backside vias 64 and the backside metal lines 80 formed by the methods described in FIGS. 3A-3D and 4A-4B.

For example, as illustrated in FIG. 5B and with further reference to FIGS. 3A-3D and 4A-4B, the method 118 to form the backside interconnect structure 59 includes an operation 120 by patterning the backside dielectric layer 82 and the semiconductor substrate 56 to form contact holes. The backside dielectric layer 82 may functions as a hard mask during the patterning process. The method 118 proceeds an operation 122 by forming a dielectric barrier 66 on the sidewalls of the contact holes using a proper technique, such as a procedure that includes depositing one or more dielectric material (such as silicon oxide, silicon nitride, silicon oxynitride or other suitable dielectric material or a combination thereof) and applying a plasma etch to the dielectric material. The method 118 proceeds to an operation 124 by forming metal vias 64 in the contact holes as illustrated in FIG. 3B. The operation 124 may include deposition and applying a CMP process. The method 118 proceeds to an operation 126 by forming a backside interlayer dielectric layer 84 by a suitable method such as deposition and applying a CMP process. The method 118 proceeds to an operation 128 by patterning the backside interlayer dielectric layer 84 to form trenches. The method 118 proceeds to an operation 130 by forming metal lines in the trenches using a procedure including deposition and CMP process according to some embodiments.

The operation 102 to form the frontside devices (such as GAA FETs or other multi-gate devices) and the frontside interconnect structure 204 includes various operations, such as those illustrated in FIG. 5C.

In some embodiments, the method 102 fabricates a multi-gate device that includes p-type GAA transistors and n-type GAA transistors. In some embodiments, method 102 fabricates a multi-gate device that includes first GAA transistors and second GAA transistors with different characteristics, such as the first GAA transistors in a critical path and the second GAA transistors in a non-critical path. In the present embodiment, a path is defined as a route to distribute signal in a circuit. A critical path is the place that mainly dominates the circuit speed (or signal distribution speed) that is dependent on different circuit applications. On the other hand, if the circuit speed is varied with transistors' performance significantly, then the signal path will be referred to as critical path. In some respects, the critical path and the non-critical GAA path may have different power consumptions during field operations. In an integrated circuit, the electrical current (and also electrical power) in the circuit may be nonuniformly distributed. Average current densities in some local areas are greater than those in other local areas. Those areas with greater average current densities are referred to as critical paths, which leads to various concerns, such as reducing power efficiency, degrading circuit performance, decreasing circuit speed, increasing battery size, and causing reliability issues. In the existing method, device dimensions, such as channel widths of the transistors in the critical paths are increased to adjust or reduce the corresponding average current density. However, the existing method will increase other issues. For example, the circuit areas are increased, and the packing density is reduced. In other examples, adjustment to the dimensions of the devices in the critical paths introduces jog in an active region that further increase circuit layout complexity and challenges circuit design due to the smaller circuit cell height and gate pitch in advanced technology nodes.

The disclosed multigate device and the method making the same addresses those concerns. Particularly, for performance boosting, the present disclosure chooses high driving devices (or devices with greater number sheet number devices) at critical path; and low power devices (or less sheet number devices) at non-critical path.

At block 132, a semiconductor layer stack is formed over a substrate. The semiconductor layer stack includes first semiconductor layers and second semiconductor layers stacked vertically in an alternating configuration. At block 134, a gate structure is formed over a first region of the semiconductor layer stack and. The gate structure includes a dummy gate stack and gate spacers. At block 136, portions of the semiconductor layer stack in second regions are removed to form source/drain recesses. At block 138, inner spacers are formed along sidewalls of the first semiconductor layers in the semiconductor layer stack. At block 140, epitaxial source/drain features are formed in the source/drain recesses. At block 142, an interlayer dielectric (ILD) layer is formed over the epitaxial source/drain features. At block 144, the dummy gate stack is removed, thereby forming a gate trench that exposes the semiconductor layer stack in a gate region. At block 146, the first semiconductor layers are removed from the semiconductor layer stack exposed by the gate trench, thereby forming gaps between the second semiconductor layers. At block 148, gate stacks are formed in the gate trench around the second semiconductor layers in the gate region. At block 150, other fabrication processes, including forming an interconnect structure, are performed from the frontside of the workpiece. Additional processing is contemplated by the present disclosure. Additional steps can be provided before, during, and after method 102, and some of the steps described can be moved, replaced, or eliminated for additional embodiments of method 102.

The present disclosure provides for many different embodiments. The disclosed device structure and the method making the same are related to field-effect transistors (FETs), especially GAA FET structure. The disclosed device structure includes various structure features and fabrication steps to provide collective isolation and prevent the device structure from current leakage. The disclosed structure having one One-Time-Programmable Memory (OTP) device and the method making the same is taken as an example. Furthermore, the disclosed structure and method are also compatible with other fabrication technologies without enhanced the circuit packing density and power efficiency.

The present disclosure provides an integrated circuit (IC) and methods for fabricating such. In one example aspect, an exemplary integrated circuit structure includes a semiconductor substrate having a frontside and a backside; a shallow trench isolation (STI) structure formed in the semiconductor substrate and defining an active region, wherein the STI structure includes a STI bottom surface, wherein the semiconductor substrate includes a substrate bottom surface, and wherein the STI bottom surface and the substrate bottom surface are coplanar; a field-effect transistor (FET) over the active region and formed on the frontside of the semiconductor substrate; and a backside dielectric layer disposed on the substrate bottom surface and the STI bottom surface.

In another example aspect, the present disclosure provides a method of making an integrated circuit (IC) structure. The method includes receiving a semiconductor substrate having a frontside and a backside; forming a circuit structure having semiconductor devices on the frontside of the semiconductor substrate and an interconnect structure over the semiconductor devices; and thinning down the semiconductor substrate from the backside of the semiconductor substrate such that an isolation structure is exposed.

In yet another example aspect, the present disclosure provides an integrated circuit (IC) structure. The IC structure includes a semiconductor substrate having a frontside and a backside; a shallow trench isolation (STI) structure formed in the semiconductor substrate and defining an active region, wherein the STI structure includes a STI bottom surface, wherein the semiconductor substrate includes a substrate bottom surface, and wherein the STI bottom surface and the substrate bottom surface are coplanar; a field-effect transistor (FET) over the active region and formed on the frontside of the semiconductor substrate; and a backside dielectric layer disposed on the substrate bottom surface and the STI bottom surface. The active region includes multiple channel layers vertically stacked and spaced away from each other; the FET includes a source, a drain, a gate interposed between the source and the drain; the gate is further extending to wrap around each of the multiple channel layers; and each of the source and drain further includes a dielectric material layer embedded in an epitaxial semiconductor feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) structure, comprising:
a semiconductor substrate having a frontside and a backside;
a shallow trench isolation (STI) structure formed in the semiconductor substrate and defining an active region, wherein the STI structure includes a STI bottom surface, wherein the semiconductor substrate includes a substrate bottom surface, and wherein the STI bottom surface and the substrate bottom surface are coplanar;
a field-effect transistor (FET) over the active region and formed on the frontside of the semiconductor substrate; and
a backside dielectric layer disposed on the substrate bottom surface and the STI bottom surface.

2. The IC structure of claim 1, wherein
the active region includes multiple channel layers vertically stacked and spaced away from each other; and
the FET includes a source, a drain, a gate interposed between the source and the drain, wherein the gate is further extending to wrap around each of the multiple channel layers.

3. The IC structure of claim 2, wherein each of the source and the drain further includes a dielectric material layer embedded in an epitaxial semiconductor feature.

4. The IC structure of claim 2, wherein each of the source and the drain further includes a dielectric material layer disposed on a bottom surface of an epitaxial semiconductor feature and isolating the epitaxial semiconductor feature from the semiconductor substrate.

5. The IC structure of claim 2, further comprising a backside via formed on the backside of the semiconductor substrate, wherein
the backside via is partially embedded in the semiconductor substrate; and
the backside via includes a conductive plug with a dielectric layer surrounding a sidewall of the conductive plug and separating the conductive plug from the semiconductor substrate.

6. The IC structure of claim 5, wherein a bottom surface of the backside via is coplanar with a bottom surface of the backside dielectric layer.

7. The IC structure of claim 5, wherein the backside via is extending to electrically connecting to one of the source and the drain.

8. The IC structure of claim 5, further comprising a backside dielectric via extending to contact one of the source and the drain.

9. The IC structure of claim 8, wherein the backside dielectric via is surrounded by the semiconductor substrate and laterally contacts the backside dielectric layer.

10. A method of making an integrated circuit (IC) structure, comprising:
receiving a semiconductor substrate having a frontside and a backside;
forming a circuit structure having semiconductor devices on the frontside of the semiconductor substrate and an interconnect structure over the semiconductor devices; and
thinning down the semiconductor substrate from the backside of the semiconductor substrate such that an isolation structure is exposed.

11. The method of claim 10, wherein the isolation structure is a shallow trench isolation (STI) structure formed in the semiconductor substrate and defining an active region of the semiconductor substrate, wherein the thinning down the semiconductor substrate includes thinning down the semiconductor substrate such that a bottom surface of the STI structure and a bottom surface of the semiconductor substrate are coplanar.

12. The method of claim 11, further comprising forming a backside dielectric layer from the backside of the semiconductor substrate to contact the bottom surface of the semiconductor substrate and the bottom surface of the STI structure.

13. The method of claim 12, further comprising
forming multiple channel layers vertically stacked and distanced from each other;
forming source/drain (S/D) features to electrically connect the multiple channel layers; and
forming a gate structure wrapping around each of the multiple channel layers.

14. The method of claim 13, wherein the forming S/D features includes forming a dielectric material layer embedded in each of the S/D features.

15. The method of claim 14, further comprising forming a conductive via in the semiconductor substrate from the backside, wherein the conductive via is electrically connecting to one of the S/D features.

16. The method of claim 15, wherein the forming a conductive via in the semiconductor substrate further includes forming a metal plug and forming a dielectric material layer surrounding the metal plug and laterally separating the metal plug from the semiconductor substrate.

17. The method of claim 15, further comprising forming a dielectric plug in the semiconductor substrate from the backside, wherein the dielectric plug is aligned with one of the S/D features and laterally contacts the backside dielectric layer.

18. An integrated circuit (IC) structure, comprising:
a semiconductor substrate having a frontside and a backside;
a shallow trench isolation (STI) structure formed in the semiconductor substrate and defining an active region, wherein the STI structure includes a STI bottom surface, wherein the semiconductor substrate includes a substrate bottom surface, and wherein the STI bottom surface and the substrate bottom surface are coplanar;
a field-effect transistor (FET) over the active region and formed on the frontside of the semiconductor substrate; and
a backside dielectric layer disposed on the substrate bottom surface and the STI bottom surface, wherein
the active region includes multiple channel layers vertically stacked and spaced away from each other,
the FET includes a source, a drain, a gate interposed between the source and the drain, wherein the gate is further extending to wrap around each of the multiple channel layers, and
each of the source and drain further includes a dielectric material layer embedded in an epitaxial semiconductor feature.

19. The IC structure of claim 18, further comprising a backside conductive via and a backside dielectric via formed on the backside of the semiconductor substrate, wherein
the backside conductive via is partially embedded in the semiconductor substrate and is electrically connected to one of the source and the drain;
the backside conductive via includes a conductive plug with a dielectric layer laterally surrounding a sidewall of the conductive plug and separating the conductive plug from the semiconductor substrate; and
the backside dielectric via is aligned to and contacts another one of the source and the drain.

20. The IC structure of claim 19, wherein
a bottom surface of the backside conductive via and a bottom surface of the backside dielectric via are coplanar; and
the backside dielectric via is surrounded by the semiconductor substrate and laterally contacts the backside dielectric layer.
